(19) United States
(12) Patent Application Publication
(10) Pub. No.: US 2025/0223694 A1
(43) Pub. Date: Jul. 10, 2025

(54) SUBSTRATE PROCESSING APPARATUS, SUBSTRATE PROCESSING METHOD, AND FILTER

(71) Applicant: Tokyo Electron Limited, Tokyo (JP)

(72) Inventors: Tomoya ONITSUKA, Kumamoto (JP); Takashi MACHINAGA, Kumamoto (JP); Seiya FUKUMARU, Kumamoto (JP)

(73) Assignee: Tokyo Electron Limited, Tokyo (JP)

(21) Appl. No.: 19/001,830

(22) Filed: Dec. 26, 2024

(30) Foreign Application Priority Data
Jan. 5, 2024 (JP) 2024-000836
Nov. 5, 2024 (JP) 2024-193843

(51) Int. Cl. C23C 16/44; H01L 21/67; H01L 21/677

(52) U.S. Cl. CPC C23C 16/4412; H01L 21/67017; H01L 21/6773

(57) ABSTRACT

A substrate processing apparatus according to the present disclosure to be used in patterning that is executed by exposing and developing a metal containing resist film formed on a substrate, wherein a chemical filter is arranged in the substrate processing apparatus, the chemical filter including a plurality of filter parts aligned towards a down-stream side on a flow path that supplies gas into the substrate processing apparatus to remove respective different substances in the gas, and the plurality of filter parts includes: an acid filter part that removes an acidic substance; and a base filter part that removes a basic substance.

### CROSS-REFERENCE TO RELATED APPLICATIONS

The present application claims priority to and incorporates by reference the entire contents of Japanese Patent Application No. 2024-000836 filed in Japan on Jan. 5, 2024 and Japanese Patent Application No. 2024-193843 filed in Japan on Nov. 5, 2024.

### FIELD

Exemplary embodiments disclosed herein relate to a substrate processing apparatus, a substrate processing method, and a filter.

### BACKGROUND

In a manufacturing process of a semiconductor device, a semiconductor wafer (Hereinafter, may be referred to as wafer), which is a substrate, is transferred within a system so as to execute thereon various processes. For example, as indicated in Japanese Patent Application Laid-open No. 2021-150372, gas that has passed through a filter to be cleaned is supplied into a system so that atmosphere is kept clean, in which a wafer is transferred and processed.

### SUMMARY

A substrate processing apparatus according to the present disclosure to be used in patterning that is executed by exposing and developing a metal containing resist film formed on a substrate, wherein a chemical filter is arranged in the substrate processing apparatus, the chemical filter including a plurality of filter parts aligned towards a down-stream side on a flow path that supplies gas into the substrate processing apparatus to remove respective different substances in the gas, and the plurality of filter parts includes: an acid filter part that removes an acidic substance; and a base filter part that removes a basic substance.

### BRIEF DESCRIPTION OF DRAWINGS

FIG. 1 is a plan view illustrating a wafer processing system to which a chemical filter is applied;

FIG. 2 is a vertical front cross sectional view illustrating the wafer processing system;

FIG. 3 is a schematic diagram illustrating the wafer processing system;

FIG. 4 is a vertical side cross sectional view illustrating the chemical filter according to a first embodiment;

FIG. 5 is a schematic diagram illustrating actions of the chemical filter;

FIG. 6 is a schematic diagram illustrating actions of the chemical filter;

FIG. 7 is a schematic diagram illustrating actions of the chemical filter;

FIG. 8 is a schematic diagram illustrating actions of the chemical filter;

FIG. 9 is a vertical side cross sectional view illustrating a chemical filter according to a second embodiment;

FIG. 10 is a vertical side cross sectional view illustrating a chemical filter according to the third embodiment;

FIG. 11 is a vertical side cross sectional view illustrating a part of the wafer processing system;

FIG. 12 is a vertical side cross sectional view illustrating another configuration example of the wafer processing system;

FIG. 13 is a vertical side cross sectional view illustrating a chemical filter according to a forth embodiment;

FIG. 14 is a vertical side cross sectional view illustrating another chemical filter according to the forth embodiment;

FIG. 15 is a vertical side cross sectional view illustrating a chemical filter according to a fifth embodiment;

FIG. 16 is a vertical side cross sectional view illustrating a chemical filter according to a sixth embodiment;

FIG. 17 is a vertical side cross sectional view illustrating a chemical filter according to a seventh embodiment;

FIG. 18 is a vertical side cross sectional view illustrating a chemical filter according to an eighth embodiment;

FIG. 19 is a vertical side cross sectional view illustrating another configuration example of the wafer processing system;

FIG. 20 is a vertical side cross sectional view illustrating another configuration example of the wafer processing system;

FIG. 21 is a vertical side cross sectional view illustrating another configuration example of the wafer processing system;

FIG. 22 is a plan view illustrating another configuration example of the wafer processing system;

FIG. 23 is a vertical front cross sectional view illustrating a cassette station constituting the wafer processing system;

FIG. 24 is a lateral cross sectional plan view illustrating the cassette station;

FIG. 25 is a vertical front cross sectional view illustrating an interface station constituting the wafer processing system; and

FIG. 26 is a vertical side cross sectional view illustrating a tube body including the chemical filter.

### DESCRIPTION OF EMBODIMENTS

Hereinafter, a wafer processing system as a substrate processing apparatus according to the present embodiment will be explained with reference to accompanying drawings. In the description, the same reference symbol is provided to elements having substantially the same functional configuration so as to omit duplicated explanation.

### Wafer Processing System

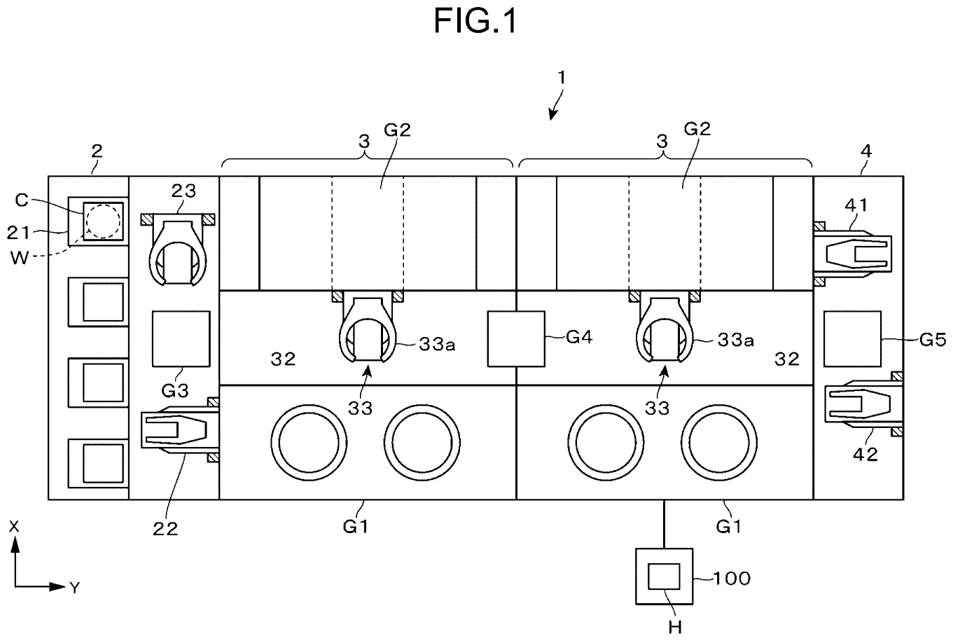

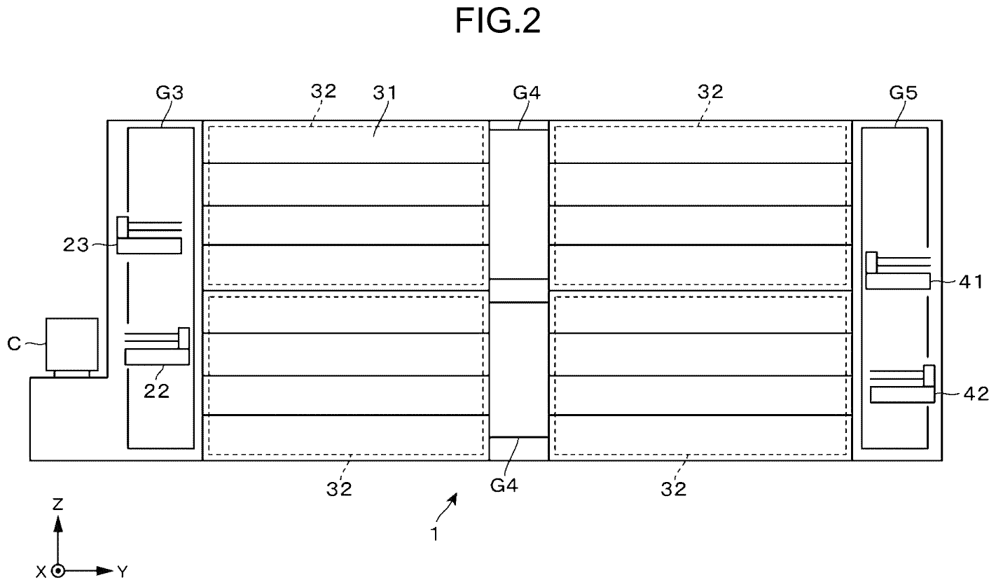

A configuration of a wafer processing system according to the present embodiment will be explained. FIGS. 1 and 2 are respectively a plan view and a front view schematically illustrating outline of a configuration of a wafer processing system 1. In the present embodiment, a case will be explained as one example in which the wafer processing system 1 is a photolithography processing system that executes a forming process and a developing process of a resist film on a wafer W that is a circular-shaped substrate.

As illustrated in FIG. 1, the wafer processing system 1 includes a cassette station 2 into/from which a cassette C having housed therein the plurality of wafers W is carried-in/out, and a processing station 3 including a plurality of various processing devices that executes predetermined processes on the wafer W. The wafer processing system 1 has a configuration being integrally connected with an interface station 4 that executes exchange of the wafer W between the cassette station 2, the processing station 3, and an exposure device (not illustrated) that is arranged side-by-side on an opposite side of the processing station 3. Note that, as illustrated in FIG. 1, the two processing stations 3 are arranged between the cassette station 2 and the interface station 4; however, the number of the two processing station 3 may be one or equal to or more than three.

A plurality of cassette placement plates 21 and wafer transferring devices 22 and 23 are arranged in the cassette station 2. The cassette station 2 causes the wafer transferring device 22 or 23 to transfer a wafer between the cassette C placed on the cassette placement plate 21 and the processing station 3. Thus, each of the wafer transferring devices 22 and 23 includes a drive mechanism with respect to directions such as an X direction, a Y direction, an up-and-down direction, and a direction around a vertical axis (namely, θ direction) as needed, and may include a drive mechanism with respect to all directions. At least one of the wafer transferring devices 22 and 23 is capable of exchanging a wafer with the cassette C, and further is capable of an exchanging operation of a wafer with the processing station 3. Note that the exchanging operation of a wafer with the processing station 3 means that a wafer is exchanged with a third block G3 including an exchanging device that can be accessed by a wafer transferring device 33 to be mentioned later in the processing station 3, for example. The third block G3 may include a plurality of exchanging devices (not illustrated) aligned in the up-and-down direction.

Note that an inspection device (not illustrated) that executes inspection on the wafer W may be arranged in a position to be accessed by at least one of the wafer transferring devices 22 and 23.

For example, a plurality of (three) blocks of first, second, and fourth blocks G1, G2, and G4 is arranged in the processing station 3. As illustrated in FIG. 2, a plurality of layers 31 each of which includes the first and second blocks G1 and G2 is laminated in the up-and-down direction. For example, the first block G1 is arranged on a front side (negative-X direction illustrated in FIG. 1) of the processing station 3, and the second block G2 is arranged on a back side (positive-X direction illustrated in FIG. 1) of the processing station 3. A fourth block G4 is arranged on a side (positive-Y direction illustrated in FIG. 1) of the interface station 4 in the processing station 3 or in a connection portion with the other adjacent processing station 3. The fourth block G4 may include a plurality of exchanging devices aligned in the up-and-down direction. Moreover, the above-mentioned third block G3 may be arranged in the processing station 3.

A plurality of processing devices, for example, a not-illustrated patterning dedicated film forming device and a not-illustrated development processing device are arranged in the first block G1. As the patterning dedicated film forming device, an anti-reflective film forming device may be included in addition to a resist film forming device, for example.

For example, the plurality of processing devices is arranged side-by-side in a horizontal direction. Note that the number, arrangements, and/or types of the above-mentioned processing devices may be arbitrarily selected.

In the above-mentioned patterning dedicated film forming device and the development processing device, predetermined processing liquid is supplied or predetermined gas is supplied onto the wafer W, for example. In this way, in the patterning dedicated film forming device, a resist film is formed which is utilized as a mask in forming a pattern of a lower layer film and/or an anti-reflective film for efficiently performing a light irradiation process such as an exposing process, for example. In the development processing device, a part of an exposed resist film is removed so as to form an uneven shape as the mask.

For example, in the second block G2, thermal treatment devices (not illustrated) configured to execute a thermal treatment such as heating and cooling on the wafers W are aligned in the up-and-down direction and the horizontal direction. In the second block G2, not-illustrated hydrophobic treatment devices configured to execute a hydrophobic treatment for improving fixation between photoresist liquid and the wafer W, and not-illustrated edge exposure devices configured to expose a peripheral portion of the wafer W are aligned in the up-and-down direction (Z direction illustrated in FIG. 2) and the horizontal direction. The numbers and arrangements of the above-mentioned thermal treatment devices, the hydrophobic treatment devices, and the edge exposure devices may be also arbitrarily selected.

As illustrated in FIG. 1, in a plan view, wafer transferring areas 32 are formed in a region between the first blocks G1 and the second blocks G2. The wafer transferring devices 33 are arranged in the wafer transferring areas 32, for example.

The wafer transferring device 33 includes a transfer arm 33a that is movable in the Y direction, the front-rear direction, the 0 direction, and the up-and-down direction, for example. The wafer transferring device 33 is capable of moving within the wafer transferring area 32 so as to transfer the wafer W to predetermined devices in the first block G1, the second block G2, the third block G3, and the fourth block G4 in the surroundings. In a case where the number of the processing stations 3 is two or more as illustrated in FIG. 1, the wafer transferring device 33, which is arranged in the processing station 3 close to the interface station 4, is able to transfer the wafer W to a predetermined device arranged in a fifth block G5 to be mentioned later in addition to the first, second, and fourth blocks G1, G2, and G4.

As illustrated in FIG. 2, the plurality of wafer transferring devices 33 is vertically arranged, for example. One of the wafer transferring devices 33 is capable of transferring the wafer W to a predetermined device located at a height of the plurality of upper layers 31 from among the plurality of vertically-laminated layers 31. Another of the wafer transferring devices 33 is capable of transferring the wafer W to a predetermined device located at a height of the plurality of layers 31 that is lower than the above-mentioned layers 31. The plurality of wafer transferring areas 32 is arranged so as to realize such a transfer of the wafer W. The number of the wafer transferring devices 33 and the number of the layers 31 which is corresponding to the single wafer transferring device 33 may be arbitrarily select, for example, the wafer transferring device 33 may be provided for each of the layers 31.

A shuttle transfer device (not illustrated) may be provided to the wafer transferring area 32, the first block G1, and/or the second block G2. The shuttle transfer device is configured to linearly transfer the wafer W between a space adjacent to one end of the processing station 3 and another space adjacent to a reverse side thereof.

The fifth block G5 including a plurality of exchanging devices, and wafer transferring devices 41 and 42 are arranged in the interface station 4. The interface station 4 causes the wafer transferring device 41 or 42 to transfer the wafer W between the fifth block G5 in which the wafer W is exchanged by the wafer transferring device 33 and an exposure machine. Thus, each of the wafer transferring devices 41 and 42 includes a drive mechanism with respect to directions such as the X direction, the Y direction, the up-and-down direction, and a direction around the vertical axis (namely, θ direction) as needed, and may include a drive mechanism with respect to all directions. At least one of the wafer transferring devices 41 and 42 is capable of supporting the wafer W so as to transfer the wafer W between an exchanging device and an exposure device in the fifth block G5.

A cleaning process device configured to clean a surface of the wafer W and the above-mentioned edge exposure device may be arranged at positions in the interface station 4 to be accessed by at least one of the wafer transferring devices 41 and 42.

The inspection device may be arranged in the cassette station 2 as described above; however, also in the processing station 3 and the interface station 4, may be arranged in a position to be accessed by one of transfer arms (33, 41, and 42 illustrated in FIG. 1 or FIG. 2) provided therein.

The above-mentioned wafer processing system 1 is provided with a control device 100. For example, the control device 100 is a computer, and further includes one or more control circuits and a program storing unit (not illustrated) so as to execute a process by a program. The program storing unit stores therein a program for controlling a process to be executed on the wafer W in the wafer processing system 1. The program storing unit stores therein a program for controlling operations of driving systems of the above-mentioned various processing devices and the transfer device so as to realize a wafer processing in the wafer processing system 1. Note that the above-mentioned program may be stored in a computer-readable storage medium H, and further may be installed in the control device 100 from the storage medium H. Commands (namely, Steps) are included in the above-mentioned program such that a control signal is output to any of units of the wafer processing system 1 by the installed program, and transfer of a substrate by each wafer transferring device and operations of processing devices are controlled by the above-mentioned control signals.

### Operations of Wafer Processing System

The wafer processing system 1 is configured as described above. Next, one example of wafer processing to be executed by using the wafer processing system 1 configured as described above will be explained.

First, the cassette C housing therein the plurality of wafers W is carried into the cassette station 2 of the wafer processing system 1, and further is placed on the cassette placement plate 21. Next, the wafer W housed in the cassette C is sequentially taken out by the wafer transferring device 22 or 23, and further is transferred into an exchanging device of the third block G3.

The wafer W having been transferred into the exchanging device of the third block G3 is transferred into a hydrophobic treatment device that is arranged in the second block G2 while being supported by the wafer transferring device 33, and a hydrophobic treatment is executed thereon. Next, being transferred into a resist film forming device by the wafer transferring device 33, a resist film is formed on the wafer W, then being transferred into a thermal treatment device and a prebaking process is executed thereon, and next, the wafer W is transferred into an exchanging device of the fifth block G5. Note that in a case where the plurality of processing stations 3 is provided as illustrated in FIGS. 1 and 2, the wafer W is placed on an exchanging device of the fourth block G4 before being transferred into an exchanging device of the fifth block G5, and then exchange thereof is executed between the plurality of wafer transferring devices 33. Note that the wafer W may be transferred as needed into an edge exposure device by the wafer transferring device 33, and further an exposing process may be executed on a periphery portion of the wafer.

The wafer W having been transferred into an exchanging device of the fifth block G5 is transferred into an exposure device by the wafer transferring devices 41 and 42, and an exposing process is executed thereon with a predetermined pattern. Note that the wafer W may be cleaned by a cleaning process device before the exposing process.

The exposing processed wafer W is transferred into an exchanging device of the fifth block G5 by the wafer transferring devices 41 and 42. Next, the wafer W is transferred into a thermal treatment device by the wafer transferring device 33, and further a post exposure bake process is executed thereon.

The post exposure bake processed wafer W is transferred into a development processing device by the wafer transferring device 33 to be developed. After completion of the development, the wafer W is transferred into a thermal treatment device by the wafer transferring device 33, and further a post baking process is executed thereon.

Next, the wafer W is transferred into an exchanging device of the third block G3 by the wafer transferring device 33, and further is transferred into the cassette C of the predetermined cassette placement plate 21 by the wafer transferring device 22 or 23 of the cassette station 2. In this way, a series of photolithography steps end.

A configuration and operations of the wafer processing system (namely, substrate processing system) according to the present disclosure are not limited to the above-mentioned ones. For example, in the mode according to the above-mentioned implementation, the wafer W is explained to be exchanged between the interface station 4 and an exposure device; however, may be indirectly connected to the exposure device. In this case, for example, the wafer W is transferred from the cassette station 2 to the processing station 3 and a necessary process is executed thereon, and further is transferred into the cassette station 2 again in order to carry out to the outside. Moreover, an unnecessary one of the above-exemplified processing devices may be omitted, or a process may be omitted in the unnecessary device.

### Regarding Resist Film

In a resist film forming device of the wafer processing system 1, a resist film is formed by using a metal containing resist. Specifically, for example, a film of metal oxide photoresist (Metal Oxide Resist: MOR) is formed. The above-mentioned metal containing resist includes metal as a configuration component of photoresist, and does not mean photoresist containing metal only as impurities. Metal of a configuration component of the photoresist is tin (Sn), for example. The above-mentioned resist film made of MOR is exposed by using light having an appropriate wave length, such as Extreme Ultra Violet (EUV), and then is developed so as to form (namely, patterning) a pattern. In the following description, a resist film is that made of MOR as long as not specifically mentioned.

The wafer processing system 1 is arranged under air atmosphere in a clean room provided in a semiconductor manufacturing factory. The wafer processing system 1 takes therein air in the surroundings of the system in order to reduce splash of particles in the system, and further supplies the air in a predetermined direction so as to form an airflow. However, a resist film made of MOR reacts with various components included in the air to be denatured, and a line width (namely, Critical Dimension: CD) of the formed photoresist pattern is changed. Note that in an evaluation test to be mentioned later, an acidic substance, more specifically, acetic acid, is exemplified as one example of a component that changes CD.

The wafer processing system 1 includes a chemical filter configured to remove a chemical substance in gas, and air that is taken into the wafer processing system 1 as described above passes through the above-mentioned chemical filter so as to form an airflow in the system. The chemical filter is constituted of a plurality of filter parts whose removal targets are different substances to be capable of removing various types of chemical substances that may change CD of a photoresist pattern, from air supplied into the wafer processing system 1. Thus, fluctuation in CD between the same-lot wafers W is reduced, and further deviation of CD from a permissible range is suppressed so that a stabilized patterning process is executed on the wafers W.

### Arrangement Example of Chemical Filter

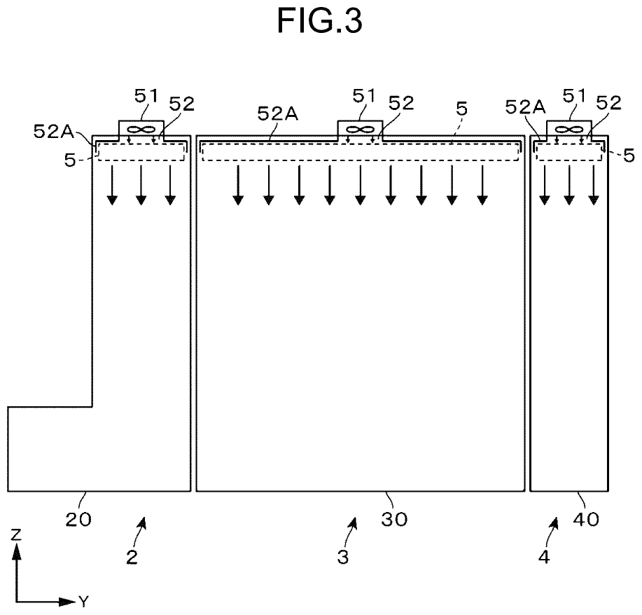

Explanation is continued with reference to a schematic front view illustrating the wafer processing system 1 in FIG. 3. The cassette station 2, the processing station 3, and the interface station 4 respectively include housings 20, 30, and 40, and inner spaces of the housings 20, 30, and 40 are configured as spaces that are partitioned separately from each other. In the spaces partitioned in such a manner, the above-mentioned transferring paths of the wafer W and the above-mentioned devices configured to execute the processes and on which the wafer W is placed are arranged, and the wafer W is transferred between stations 2 to 4 via not-illustrated openings formed in the housings 20 to 40.

In an upper portion of each of the housings 20, 30, and 40, a corresponding fan 51 is arranged. In each of the housings 20, 30, and 40, a corresponding flow path 52 extending downward from the fan 51 is arranged, and a chemical filter 5 is arranged in a ceiling portion of the corresponding housing that is a lower-stream edge portion of the flow path 52. Note that 52A illustrated in FIG. 3 are flow path forming members for forming the flow paths 52. Caused by action of the fan 51, air is taken into the flow path 52 from the outside of the wafer processing system 1, and further the taken air flows towards a down-stream side on the flow path 52. Such a flow causes the air to be supplied from the above of the chemical filter 5, to pass through the chemical filter 5, and further to be discharged from a lower portion of the chemical filter 5. The air, which has passed through the chemical filter 5 as described above and from which various chemical substances are removed, forms an airflow that flows downward in a housing.

### Configuration Example of Chemical Filter

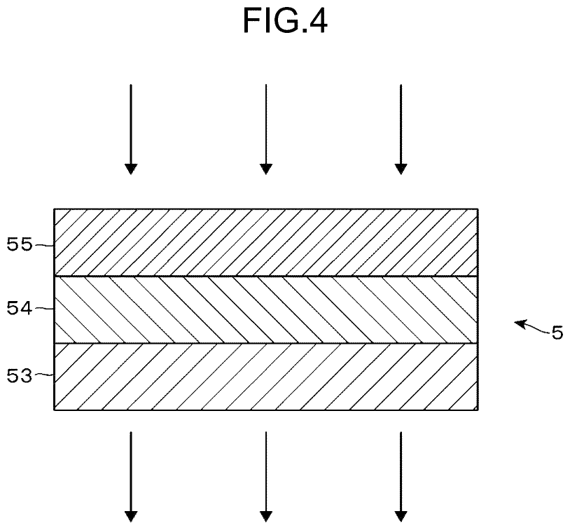

FIG. 4 is a vertical side cross sectional view illustrating the chemical filter 5. Note that arrows illustrated in FIG. 4 and the following each illustrating configurations of chemical filters indicate flowing directions of gas passing through the chemical filters. The chemical filter 5 includes an acid filter part 53 for removing an acidic substance, a base filter part 54 for removing a basic substance, and an organic filter part 55 for removing an organic substance; and the acid filter part 53, the base filter part 54, and the organic filter part 55 are laminated in this order towards an upper-stream side of the flow path 52. In the present embodiment, thicknesses (namely, sizes in flowing direction of gas) of the acid filter part 53, the base filter part 54, and the organic filter part 55 are equal to or similar to each other.

The acid filter part 53, the base filter part 54 and the organic filter part 55 may be comprehensively referred to as the filter parts 53 to 55. Note that in the present embodiment, the flow path 52 is formed along the Z direction (namely, vertical direction), a lamination direction of the filter parts 53 to 55 is also along the Z direction.

The filter parts 53 to 55 will be more specifically explained. The above-mentioned filter parts 53 to 55 are filtering materials having removal actions with respect to the above-mentioned substances. For example, the organic filter part 55 is constituted of activated carbon to be capable of adsorbing and removing various organic substances such as hydrocarbons, alcohols, ketones, eaters, and aromatic compounds. As the above-mentioned basic substance, the base filter part 54 is constituted of, for example, an ion exchanger so as to remove various amines and ammonia, and the above-mentioned ion exchanger is a strong acid cation exchange resin including a sulfonic acid group as a functional group, for example. As the above-mentioned acidic substance, the acid filter part 53 is constituted of, for example, an ion exchanger so as to remove various organic acids, such as acetic acid, and various inorganic acids such as hydrochloric acid, hydrofluoric acid, nitric acid, and sulfuric acid, and the above-mentioned ion exchanger is a strong base anion exchanger including a quaternary ammonium cation as a functional group, for example.

For example, the filter parts 53 to 55 are formed in plate-shaped, and further has a structure including many small holes through which one principal surface of the plate communicates with the other principal surface so that the supplied gas can pass through. In a case where exemplifying a specific example of the above-mentioned structure, a honeycomb structure is exemplified. Regarding the above-mentioned acid filter part 53 and the base filter part 54 that are ion exchangers, such a structure may be realized by using an ion exchange resin, for example.

Instead of employing such configurations of the filter parts 53 to 55, a fiber including a component for removing the above-mentioned chemical substances may be fabric, knitting, and/or non-woven fabric so as to be formed in plate-shaped (including sheet-shaped). The above-mentioned small holes in this case correspond to gaps that are formed between fibers. In a case where using a fiber in such a manner, the acid filter part 53 and the base filter part 54 may be formed by using an ion exchange fiber as an ion exchanger. The organic filter part 55 may be formed of activated carbon fiber.

### Action and Effects of Chemical Filter

As described above, in the chemical filter 5; the organic filter part 55, the base filter part 54, and the acid filter part 53 are arranged towards a down-stream side. In a case where providing filter parts having different removal targets in such a manner, air having passed through the chemical filter 5 is supplied to a transferring path of the wafer W and devices that execute processes on the wafer W and on which the wafer W is placed in the wafer processing system 1 in a state where various chemical substances are removed which cause fluctuation in CD of a pattern formed in a resist film. Thus, it is possible to stabilize CD of a pattern in a resist film as described above.

Incidentally, a patterning dedicated film forming device executes Edge Bead Removal (EBR) for supplying, after formation of a film, organic solvent to a periphery portion of the wafer W so as to remove an unnecessary portion, a pre-wet process for supplying organic solvent to the wafer W before formation of a film so as to improve wettability with respect to processing liquid for forming the above-mentioned film, and the like. For example, the above-mentioned organic solvent includes Propylene glycol monomethyl ether acetate (PGMEA) in some cases, and a trace amount of PGMEA is considered to leak out of the wafer processing system 1 so as to be supplied to the chemical filter 5 by the fan 51.

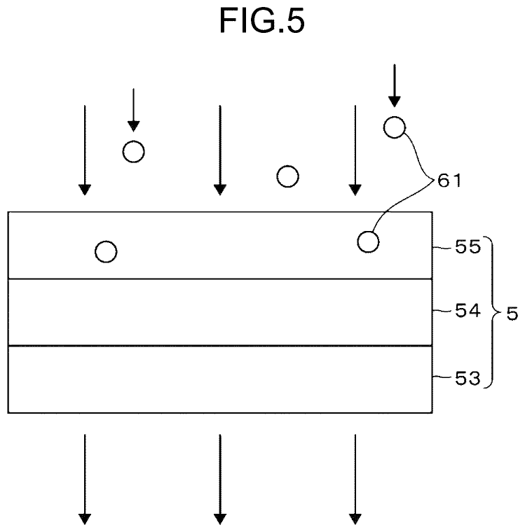

Actions of the chemical filter 5 in a case where PGMEA is supplied as an organic substance as described above will be explained with reference to FIG. 5 to FIG. 8. In FIG. 5 to FIG. 8, PGMEA in air is indicated by using a reference number of 61. For a while since the new chemical filter 5 is attached to the wafer processing system 1, the PGMEA 61 supplied to the chemical filter 5 is collected by the organic filter part 55 that is provided as a filter part on the most upper-stream side in the above-mentioned chemical filter 5 not to be discharged from the chemical filter 5 (see FIG. 5).

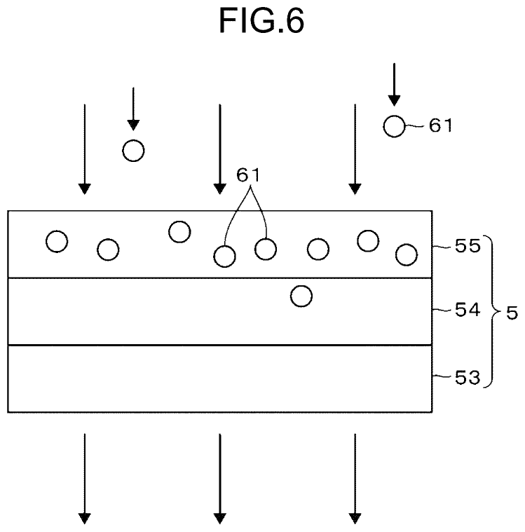

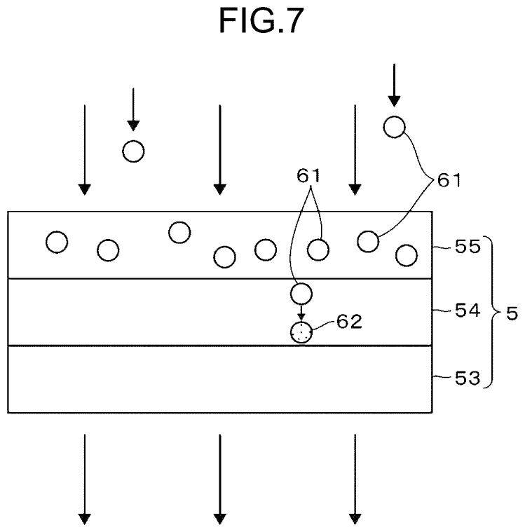

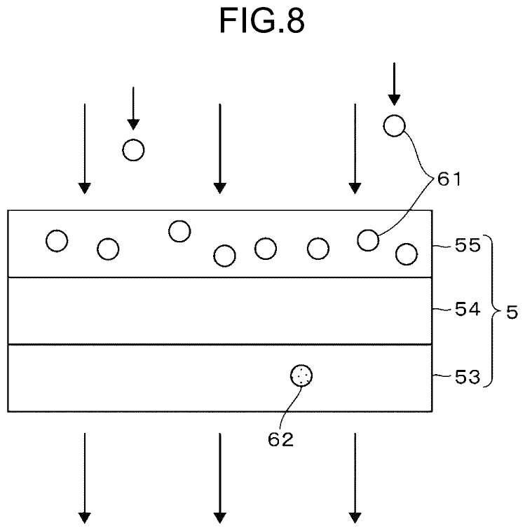

However, in a case where the above-mentioned PGMEA 61 and other organic substances are continuously supplied to the chemical filter 5 and a collection amount in the organic filter part 55 becomes large, adsorbing/removing performance of the organic filter part 55 with respect to newly-supplied organic substances reduces so that the above-mentioned performance becomes less than a permissible range thereof. In other words, the organic filter part 55 reaches the end of life thereof (see FIG. 6). Next, the PGMEA 61 supplied to the chemical filter 5 passes through the organic filter part 55 to be supplied to the base filter part 54. The PGMEA 61 is decomposed by actions of the base filter part 54 so as to generate acetic acid (see reference number 62 in FIG. 7). As described above, the acetic acid 62 causes CD of a pattern in a resist film, which is MOR, to fluctuate. However, the acid filter part 53 is arranged on a down-stream side of the base filter part 54, which is generated by the acetic acid 62 as described above, the acetic acid 62 is removed by actions of the acid filter part 53 (see FIG. 8) so as not to be discharged from the chemical filter 5.

Actions of the chemical filter 5 illustrated in FIG. 5 to FIG. 8 will be more specifically explained, the chemical filter 5 includes the filter parts 53 to 55 to be capable of removing various types of chemical substances as described above, and thus has advantage in reducing fluctuation in CD of a photoresist pattern. However, in a case where a height of a space in which the chemical filter 5 is arranged is limited, having a configuration including a filter part including a plurality of types of filtering materials, thicknesses of the filter parts 53 to 55 are relatively small. A length of life of each of the filter parts 53 to 55 is according to a thickness thereof, and thus life elongation of the above-mentioned filter parts 53 to 55 is difficult in some cases.

Thus, in a case where a concentration of an organic substance in the surroundings of the wafer processing system 1 is high, as illustrated in FIG. 5 and FIG. 6, the organic filter part 55 reaches life thereof in a relatively short time interval, and the acetic acid 62 is generated from the PGMEA 61, which causes fluctuation in CD of a photoresist pattern. However, in the chemical filter 5, on a down-stream side of the organic filter part 55, the base filter part 54 and the acid filter part 53 align towards the above-mentioned down-stream side so as not to discharge the acetic acid 62 from the chemical filter 5 as described with reference to FIG. 7 and FIG. 8.

Therefore, even in a case where the wafer processing system 1 is arranged in an environment where a concentration of an organic substance in the surroundings of the wafer processing system 1 is relatively high so that life of the organic filter part 55 is relatively short, the chemical filter 5 is not necessarily replaced before a time point when the life reaches the end thereof. In other words, according to the configuration of the chemical filter 5 provided to the wafer processing system 1, it is possible to prevent increase in replacement frequency thereof. The above mentioned leads to reduction in occurrence frequency of a state where transfer and processes with respect to the wafer W in the wafer processing system 1 are stopped for the above-mentioned replacement, so that it is possible to prevent reduction in the productivity of the wafer processing system 1.

### Second Embodiment of Chemical Filter

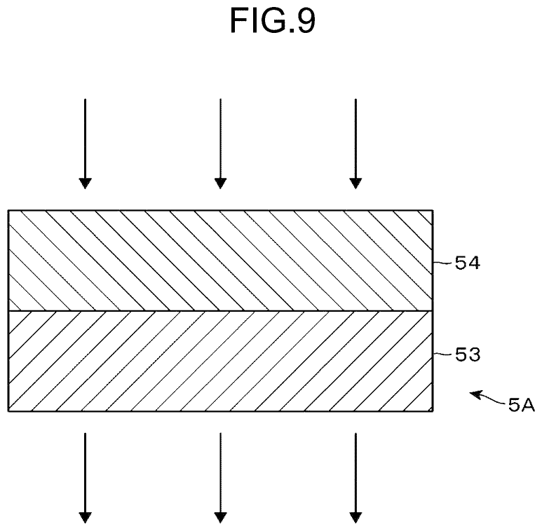

Hereinafter, another example of a chemical filter will be explained, which is provided to the wafer processing system 1 instead of the chemical filter 5. FIG. 9 is a vertical side cross sectional view illustrating a chemical filter 5A according to a second embodiment. The organic filter part 55 is not provided to the chemical filter 5A, and is constituted of the base filter part 54 and the acid filter part 53 that are laminated to each other. Similar to the chemical filter 5, regarding the alignment order of the base filter part 54 and the acid filter part 53, the acid filter part 53 is arranged lower than the base filter part 54 on a down-stream side of the flow path 52 such that the acetic acid 62 generated in the base filter part 54 can be removed by the acid filter part 53. As already described in the explanation of the chemical filter 5, in the flow path 52 on which a chemical filter is provided in the wafer processing system 1, a lower portion is a down-stream side, and thus the acid filter part 53 is arranged lower than the base filter part 54.

As described above, the chemical filter 5A is not provided with the organic filter part 55. Therefore, in providing selected one of the chemical filter 5 or the chemical filter 5A into a space having a predetermined height on the flow path 52, it is possible to set a thickness of the acid filter part 53 and/or a thickness of the base filter part 54 to be larger, in a case where the chemical filter 5A is selected. Note that a thickness of the chemical filter 5A illustrated in FIG. 9 is equal to that of the chemical filter 5 illustrated in FIG. 4, and thicknesses of the acid filter part 53 and the base filter part 54 of the chemical filter 5A are larger than those of the chemical filter 5. Examples of relation between thicknesses of filter parts in chemical filters will be more explained.

### Third Embodiment of Chemical Filter

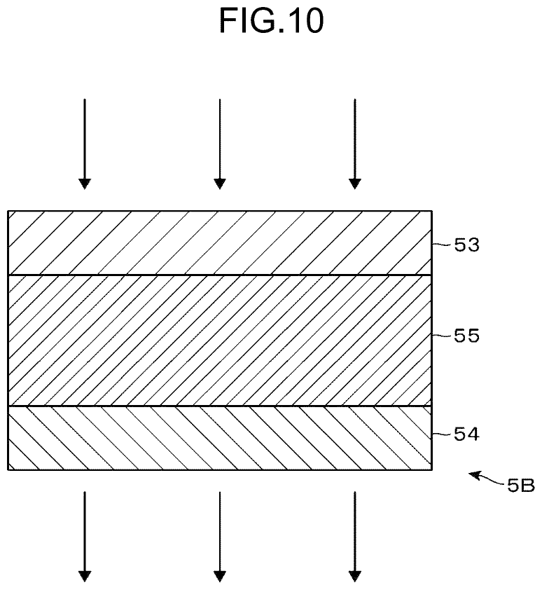

FIG. 10 is a vertical side cross sectional view illustrating a chemical filter 5B according to the third embodiment. Similar to the chemical filter 5, the acid filter part 53, the base filter part 54, and the organic filter part 55 are laminated to constitute the chemical filter 5B. Towards a down-stream side of the flow path 52, the acid filter part 53, the organic filter part 55, and the base filter part 54 are arranged in this order.

In the chemical filter 5B, a thickness of the organic filter part 55 is larger than a thickness of the acid filter part 53 and a thickness of the base filter part 54. In a case where the thicknesses are set in such a manner, a time period from when the chemical filter 5B starts to be used until the organic filter part 55 reaches the end of life thereof becomes long, even in a case where the PGMEA 61 is supplied to the chemical filter 5B during the above-mentioned long time period, the PGMEA 61 does not reach the base filter part 54, so that it is possible to prevent generation of the acetic acid 62 in the above-mentioned base filter part 54 and discharge of the above-mentioned acetic acid 62 from the chemical filter 5B. Thus, similar to the chemical filter 5, the chemical filter 5B is also capable of reducing the replacement frequency even in a case where being used in an environment where an organic substance concentration is relatively high.

Note that even in a case where an organic substance other than PGMEA and/or a compound that is generated by a reaction such as decomposition of the above-mentioned organic substance affect CD of a photoresist pattern, as indicated in the chemical filter 5B, if a thickness of the organic filter part 55 is large, it is possible to collect the above-mentioned organic substance for a long period. In other words, even in a case where an organic substance other than PGMEA causes fluctuation in CD of a photoresist pattern, according to the configuration of the chemical filter 5B in which relation between thicknesses of the filter parts 53 to 55 is the above-mentioned relation, it is preferable because the replacement frequency of the chemical filter 5B can be reduced. A thickness of the organic filter part 55 in the chemical filter 5, which has been already described with reference to FIG. 4, may be larger than a thickness of the acid filter part 53 and a thickness of the base filter part 54 so as to further reduce the replacement frequency.

### Other Arrangement Examples of Chemical Filter

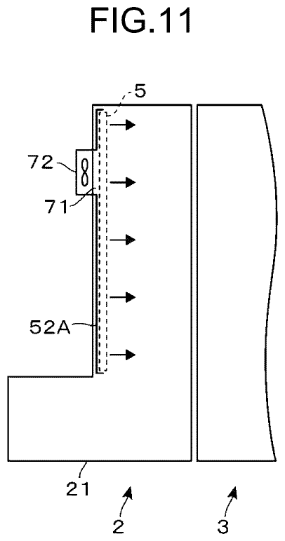

There have been explained cases where a chemical filter is arranged on the flow path 52 through which air forming a down air flow passes; however, the arrangement is not limited thereto. In FIG. 11, an example is indicated in which the chemical filter 5 is arranged on the flow path 71 that is arranged on a side wall of the cassette station 2. A fan 72 causes air taken from the outside of the wafer processing system 1 flows along the flow path 71 in a lateral direction so as to pass through the chemical filter 5, and further forms an airflow that flows in a lateral direction in the housing 20. Thus, the filter parts 53 to 55 are aligned in a lateral direction. As indicated in the example illustrated in FIG. 11, not limited to a system configuration in which gas is supplied to a chemical filter from the above, an arrangement direction of a chemical filter and a supply direction of gas via the chemical filter can be arbitrarily set. In a station other than the cassette station 2, a chemical filter may be arranged such that gas flowing in a lateral direction passes through in a housing thereof.

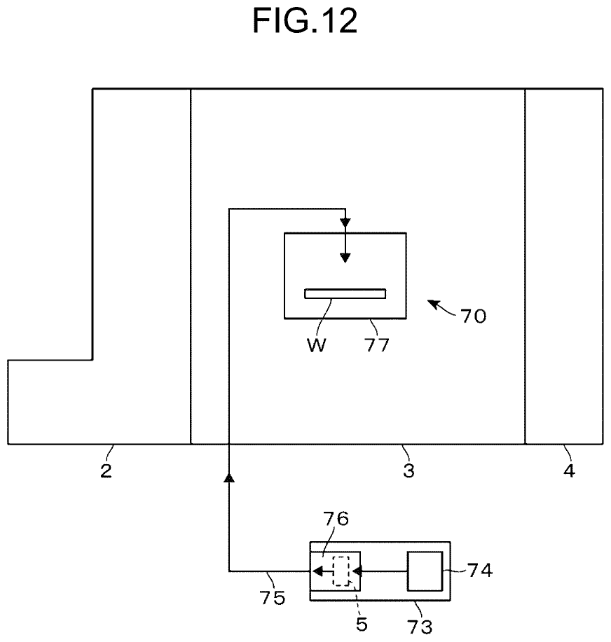

In FIG. 12, an example is illustrated in which a gas supplying system 73 is connected to the wafer processing system 1. The gas supplying system 73 is a system that is arranged outside of the wafer processing system 1, and further includes a supply mechanism 74 that supplies gas adjusted such that the temperature and the humidity thereof are within predetermined ranges. The gas supplying system 73 and a processing device 70 arranged in the processing station 3 are connected via a pipe 75. In the gas supplying system 73, a flow path 76 arranged on an upper-stream side of the pipe 75 is provided with the chemical filter 5, and gas supplied from the supply mechanism 74 passes through the chemical filter 5 to be supplied to the processing station 3 via the pipe 75.

The gas whose temperature and humidity are adjusted in such a manner is inert gas such N2 gas. A housing 77 is included as the processing device 70 to which the above-mentioned inert gas is supplied, a processing space for processing the wafer W is formed in the housing 77, and the above-mentioned inert gas is supplied to the processing space. Thus, the above-mentioned processing space is a space that is formed in the housing 30 of the processing station 3 by the housing 77, and further is partitioned from the wafer transferring area 32 to which air is supplied from the chemical filter 5 of a ceiling portion. As the processing device 70, a patterning film forming device and a heating device are exemplified, for example.

Note that as inert gas supplied from the gas supplying system 73 via the chemical filter 5, not limited to supplying thereof to a processing device of the wafer W. For example, in the processing station 3, assume that a waiting device that causes the plurality of wafers W to wait in a waiting dedicated space surrounded by the housing 77 to be partitioned from the wafer transferring area 32. The inert gas may be supplied to the above-mentioned waiting dedicated space. Note that the waiting device may be provided in a station other than the processing station 3, such as the cassette station 2. A supply target of the inert gas may be the cassette placement plate 21 in the cassette station 2, and the inert gas is supplied into the cassette C, in which the wafers W are waiting, via a not-illustrated gas supplying port of the cassette placement plates 21. The cassette C is a transfer container called a Front Opening Unify Pod (FOUP), for example, and further is configured to be capable of executing gas supply from the outside into an inner part. As described above, a supply target of the inert gas from the gas supplying system 73 is not limited to the processing station 3.

In FIG. 11 and FIG. 12, examples employing the chemical filter 5 are exemplified; however, the chemical filters 5A and 5B and chemical filters to be mentioned later may be employed instead of the chemical filter 5. Furthermore, the gas supplying system 73 may employ the chemical filters 5A and 5B and chemical filters to be mentioned later instead of the chemical filter 5. As indicated in the example illustrated in FIG. 12, gas supplied to the chemical filters is not limited to air, and an arrangement position of the chemical filter may be apart from a transferring path of the wafer W and/or a housing storing therein the processing device 70.

### Further Configuration Example of Chemical Filter

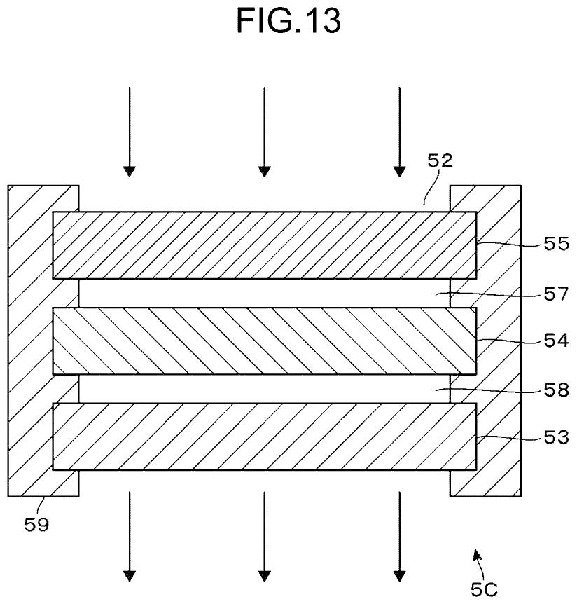

FIG. 13 is a vertical side cross sectional view illustrating a chemical filter 5C according to a forth embodiment. Similar to the chemical filter 5, the chemical filter 5C is configured such that the organic filter part 55, the base filter part 54, and the acid filter part 53 are aligned towards a down-stream side of the flow path 52, gaps 57 and 58 are respectively formed between the organic filter part 55 and the base filter part 54, and between the base filter part 54 and the acid filter part 53.

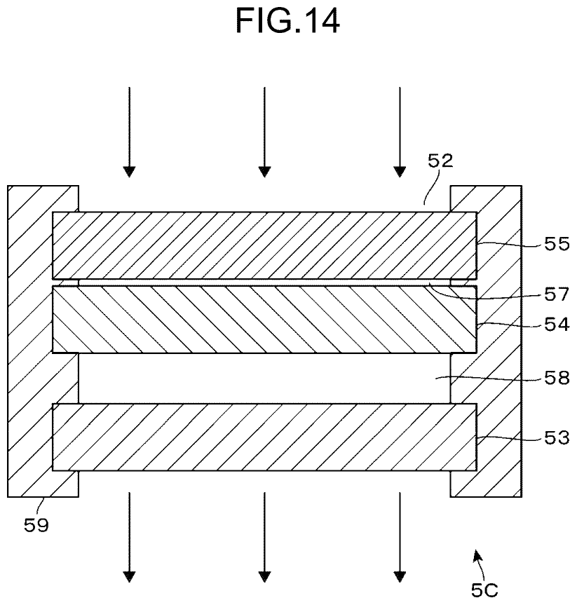

Therefore, the chemical filter 5C is configured such that a gap is arranged between one filter part and another filter part that is arranged next to the one filter part when the flow path 52 is viewed towards a down-stream side. Note that a reference number 59 illustrated in FIG. 13 is a tubular frame surrounding side peripheries of the filter parts 53 to 55 so as to form the flow path 52, and further supports the filter parts 53 to 55 so as to form the gaps 57 and 58. In the example illustrated in FIG. 13, the gaps 57 and 58 have the same width; however, widths thereof may be different from each other. An example is illustrated in FIG. 14 in which a width of the gap 57 is smaller than a width of the gap 58.

As described above, a configuration may be employed in which adjacent filter parts of the filter parts 53 to 55 are not in contact with each other. Note that life of the filter part is according to a thickness thereof as described above. In terms of arranging a chemical filter in a limited arrangement space of a chemical filter in the system, and further arranging filter parts such that life thereof is long, it is preferable that adjacent ones of the filter parts are arranged in contact with each other.

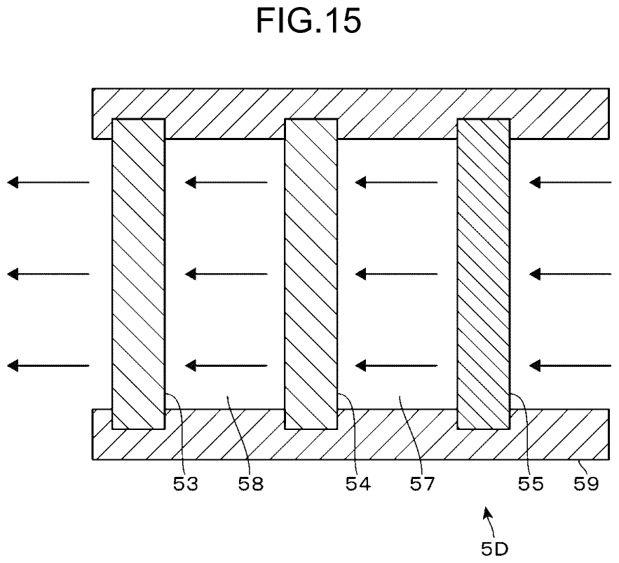

FIG. 15 is a vertical side cross sectional view illustrating a chemical filter 5D according to a fifth embodiment. Similar to the chemical filter 5C, the chemical filter 5D is configured such that the organic filter part 55, the base filter part 54, and the acid filter part 53 are aligned towards a down-stream side of the flow path 52. Note that the flow path 52 is formed in a lateral direction, and thus the filter parts 53 to 55 are aligned along the lateral direction. The filter parts 53 to 55 are arranged in a frame 59 such that they are separated from each other by relatively large intervals. In other words, the widths of the gaps 57 and 58 illustrated in FIG. 13 and FIG. 14 are increased.

As indicated in the example illustrated in FIG. 15, the filter parts may be separated by relatively large intervals, not limited to being arranged close to each other. Even in a case where the filter parts are separated by relatively large intervals, assume that a chemical filter is configured by filter parts from a filter part (namely, organic filter part 55 in the present embodiment) arranged on the most upper-stream side of a flow path to a filter part (namely, acid filter part 53 in the present embodiment) arranged on the most down-stream side of the flow path.

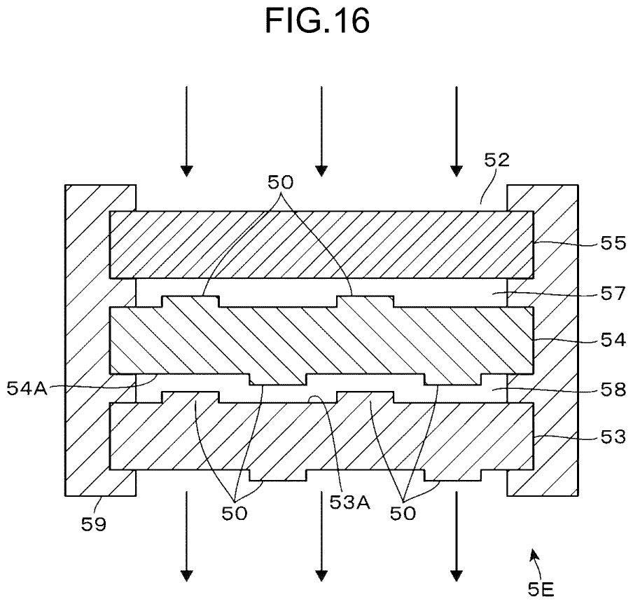

FIG. 16 is a vertical side cross sectional view illustrating a chemical filter 5E according to a sixth embodiment. The chemical filter 5E has a configuration that is substantially the same as that of the chemical filter 5C illustrated in FIG. 13, as a different point, protrusions 50 are provided to the base filter part 54 and the acid filter part 53. The protrusions 50 protrude towards both of an upper-stream side and a down-stream side of the flow path 52 so as to form unevenness on principal surfaces of the base filter part 54 and the acid filter part 53, and thus surface areas of the principal surfaces become relatively large so as to improve removing performance of chemical substances. Note that the protrusions 50 are not protrusions that are inevitably formed in a manufacturing process of filter parts, and heights thereof are equal to more than 0.5 mm, for example.

Incidentally, when viewed along a flowing direction of gas, in the chemical filter 5E, the protrusions 50 formed on an opposite surface 54A, facing the acid filter part 53, of the base filter part 54 and the protrusions 50 formed on an opposite surface 53A, facing the base filter part 54, of the acid filter part 53 are overlapped with each other. Therefore, it is possible to prevent increase in a width of the gap 58 between the acid filter part 53 and the base filter part 54, so that it is preferable because increase in size of the chemical filter 5E is suppressed.

In the chemical filter 5E, the protrusion 50 is not provided to the organic filter part 55; however, similar to the base filter part 54 and the acid filter part 53, the protrusion(s) 50 may be provided to the organic filter part 55. Note that in a case where employing a configuration including the protrusions 50 in such a manner, a thickness of each of the filter parts 53 to 55 means a thickness of a portion without the protrusion 50.

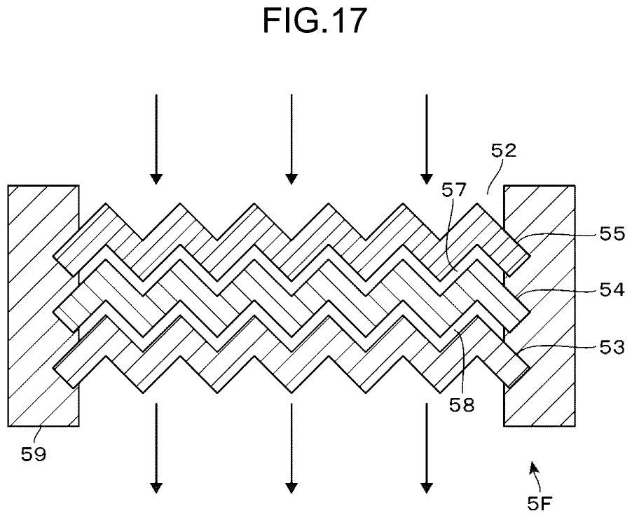

As indicated in the example of the chemical filter 5E, the filter parts 53 to 55 are not limitedly formed in plate-shaped as the examples of the chemical filters 5 and 5A to 5D. FIG. 17 is a vertical side cross sectional view illustrating a chemical filter 5F according to a seventh embodiment as examples of other chemical filters in a case where the filter parts 53 to 55 are not formed in plate-shaped. Each of the filter parts 53 to 55 in the chemical filter 5F is formed in plate-shaped obtained by repeating a portion that is mountain-folded and a portion that is valley-folded from one end side towards another end side, so as to be formed in wave-shaped in a side view. Note that in the example illustrated in FIG. 17, the filter parts 53 to 55 are formed in pleat-shaped by making folds; however, may have a shape of a wave-shaped curve without folds in a side view.

In a case where the filter parts 53 to 55 are formed in wave-shaped in a side view as described above, a surface area towards an upper-stream side of the flow path 52 is increased, so that it is possible to improve removing performance of chemical substances. Note that in the example illustrated in FIG. 16, the gaps 57 and 58 are arranged between the filter parts 53 to 55; however, a configuration without the gaps 57 and 58 may be employed.

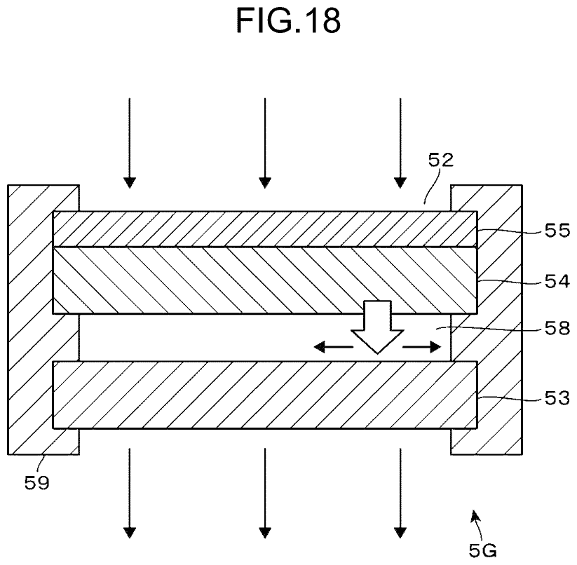

FIG. 18 is a vertical side cross sectional view illustrating a chemical filter 5G according to the eighth embodiment. The chemical filter 5G is configured substantially similarly to the chemical filter 5C illustrated in FIG. 13, the gap 57 between the filter parts 54 and 55 is not provided as a different point.

Assume that a supply amount of an organic substance varies depending on a portion of the organic filter part 55, one position reaches the end of life thereof earlier than another position, and the PGMEA 61 is supplied to the base filter part 54 from the above-mentioned one position. In other words, assume that the PGMEA 61 is locally supplied to the base filter part 54 from a partial position of the organic filter part 55. In this case, the acetic acid 62 occurs in a local position of the base filter part 54 to be discharged towards the acid filter part 53 as indicated by a relatively thick arrow illustrated in FIG. 18. Note that the above-mentioned acetic acid 62 diffuses in the gap 58 between the acid filter part 53 and the base filter part 54 so as to prevent supply of the acid filter part 53 to a local position alone. In other words, in a case where the gap 58 is provided, it is possible to prevent a case where a local position of the acid filter part 53 reaches the end of life thereof earlier than another position of the acid filter part 53 so as not to be able to remove the acetic acid 62, as a result, it is possible to reduce replacement frequency of the chemical filter 5G.

The already-described chemical filter to which the gap 58 is provided between the base filter part 54 and the acid filter part 53 similarly to the above-mentioned chemical filter 5G is able to achieve effects similar to the above-mentioned chemical filter 5G. In a case where the gap 57 between the organic filter part 55 and the base filter part 54 is additionally provided similarly to the chemical filter 5C illustrated in FIG. 13, the PGMEA 61 diffuses via the above-mentioned gap 57, and then is supplied to the base filter part 54. Therefore, it is preferable because it is possible to reliably prevent a case where life of the above-mentioned local position of the acid filter part 53 reduces.

### Arrangement of Different Chemical Filters in the Same System

From among the already-described chemical filters, the same chemical filters may be provided to the wafer processing system 1; however, different chemical filters may be provided thereto. In consideration of sizes of arrangement spaces for chemical filters in portions in a system, concentrations of chemical substances in the surroundings of arrangement positions, and the like; appropriate chemical filters can be selected and arranged. More specifically, chemical filters respectively provided to flow paths connected to spaces that are partitioned from each other may have configurations that are different from each other. Hereinafter, such examples will be explained with reference to drawings.

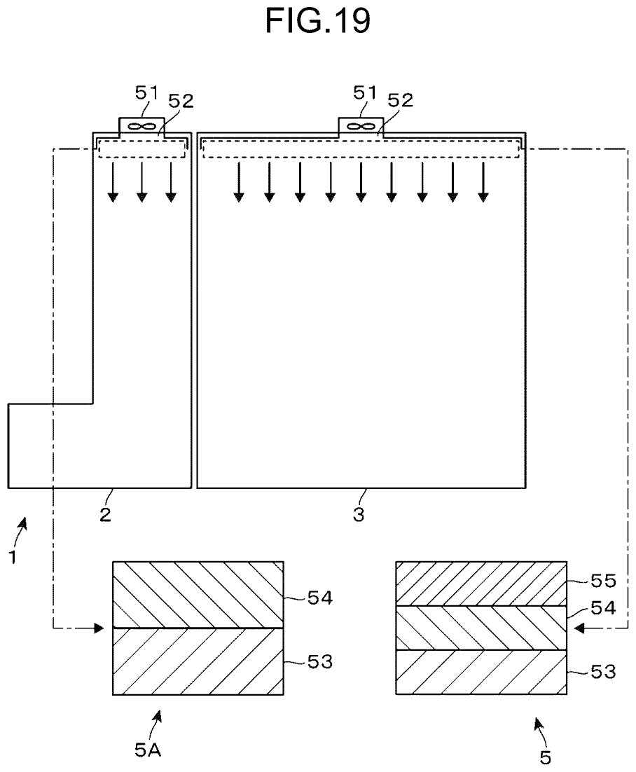

In an example illustrated in FIG. 19, in the wafer processing system 1, the chemical filter 5A having been explained with reference to FIG. 9 is provided to the flow path 52 (namely, first flow path) in a ceiling portion of the cassette station 2, and further the chemical filter 5 having been explained with reference to FIG. 4 is provided to the flow path 52 (namely, second flow path) in a ceiling portion of the processing station 3. Moreover, air is respectively supplied to the housing 20 that is a first space and the housing 30 that is a second space from the chemical filter 5A (namely, first chemical filter) and the chemical filter 5 (namely, second chemical filter).

In the present embodiment, in consideration of the fact that concentrations of various organic substances are high in the surroundings of the processing station 3 in which organic solvent is used, the chemical filter 5 including the organic filter part 55 is provided in a ceiling portion of the processing station 3 in order to improve removal effects thereof. On the other hand, the chemical filter 5A without the organic filter part 55 is provided to a ceiling portion of the cassette station 2 in consideration of the fact that concentrations of organic substances in the surroundings of the cassette station 2 are lower than those in the surroundings of the processing station 3. Not including the organic filter part 55, in the chemical filter 5A, the acid filter part 53 and the base filter part 54 are configured to be relatively thick so as to effectively utilize arrangement spaces, thereby leading to life elongation. Specifically, a thickness of the acid filter part 53 and a thickness of the base filter part 54 of the chemical filter 5A are set to be larger than those of the chemical filter 5 so as to realize life elongation of the chemical filter 5A.

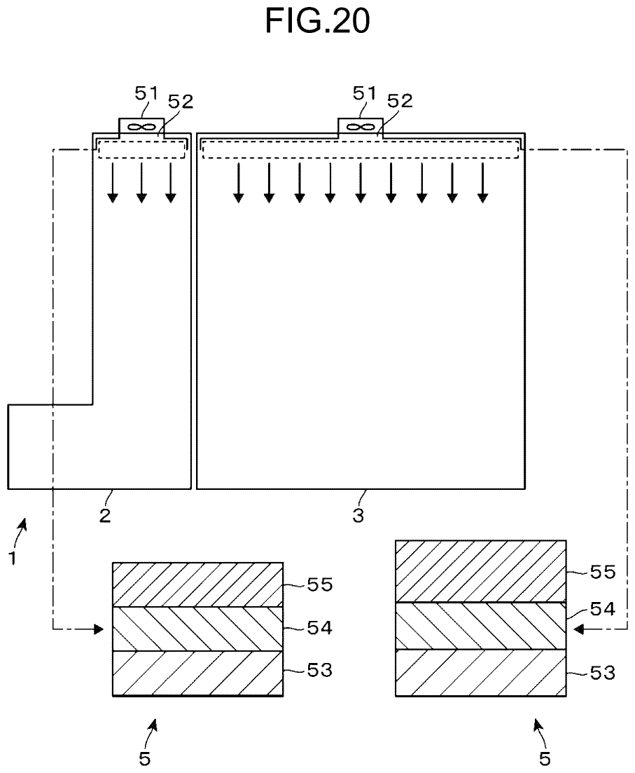

Another arrangement example is illustrated in FIG. 20. In the wafer processing system 1 illustrated in FIG. 20, the processing station 3 has a larger height of a region in which a chemical filter can be arranged. In ceiling portions of the cassette station 2 and the processing station 3, the respective chemical filters 5 are arranged, and a thickness of the organic filter part 55 of the chemical filter 5 in the processing station 3 is larger than that of the chemical filter 5 in the cassette station 2 so that the above-mentioned arrangement region can be effectively utilized. Thus, life elongation of the chemical filter 5 in the processing station 3 is attempted.

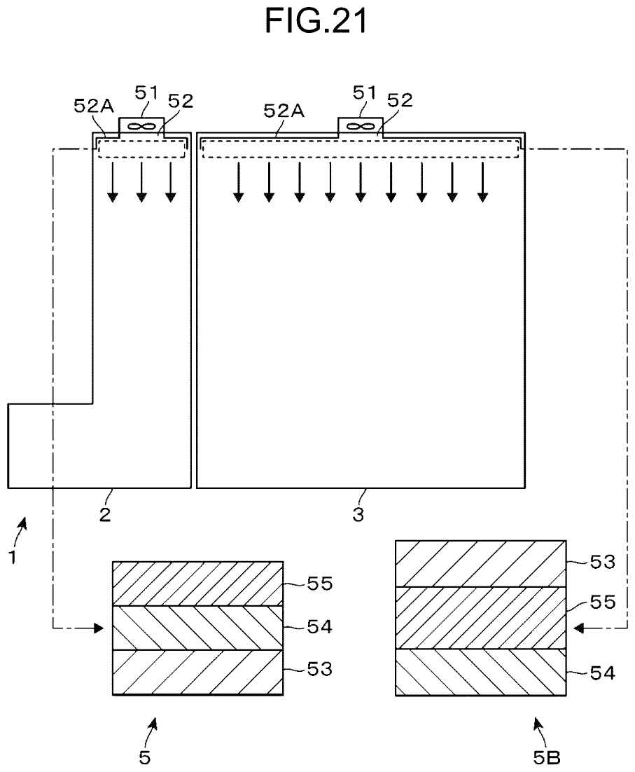

Further other arrangement example is illustrated in FIG. 21. In the above-mentioned example, the chemical filter 5 is arranged in a ceiling portion of the cassette station 2, on the other hand, the chemical filter 5B in which a thickness of the organic filter part 55 is larger than thicknesses of other filter parts illustrated in FIG. 10 is arranged in a ceiling portion of the processing station 3 so that a chemical filter of the processing station 3 has a long life.

As described above, between chemical filters arranged in different positions in the wafer processing system 1, it is possible to select whether or not including the organic filter part 55, change an alignment order of included filter parts on a flow path, or change a thickness of any of the included filter parts.

Note that in differentiating a thickness of a filter part between chemical filters in different positions of the wafer processing system 1, the example has been indicated in which a thickness of the organic filter part 55 is different; however, a thickness of the base filter part 54 and/or the acid filter part 53 may be differentiated. For convenience of explanation, concentrations of organic substances are assumed to be higher in the surroundings of the processing station 3, and the organic filter part 55 is indicated to include the processing station 3, or a chemical filter in which the organic filter part 55 has a long life is indicated to be arranged; however, not limited to the above-mentioned arrangements. In other words, the chemical filter having been explained to be arranged in the processing station 3 may be arranged in the cassette station 2, and further the chemical filter having been explained to be arranged in the cassette station 2 may be arranged in the processing station 3. A configuration of a chemical filter having been explained to be different between the cassette station 2 and the processing station 3; however, a configuration of a chemical filter may be set to be different from another station.

### Divided Configuration of System

The wafer processing system 1 that is a substrate processing apparatus executes a series of patterning from formation to development of a patterning film as described above; however, not limited to such a system configuration. A plurality of device units that respectively carry on different parts of the above-mentioned series of patterning is configured to be arranged in a clean room. A wafer processing system may have a configuration in which a transfer mechanism in the clean room sequentially transfers the cassette C between the device units, and further the wafer W, which is taken out from the cassette C, is transferred and processed in each of the device units, so as to execute a patterning process. The substrate processing apparatus is a device that causes the wafer W carried out from the cassette C to be processed and then to be returned to the cassette C again, and thus the plurality of device unit respectively corresponds to the substrate processing apparatus. As described above, the substrate processing apparatus may be configured as a device unit that carries on a part of steps of a patterning process, and each of the device units may be provided with the corresponding above-described chemical filter.

Further explaining the device unit, in a case of a device unit to which an exposure device is not connected, the cassette station 2 that transfers the wafer W between the device unit and the cassette C, and the processing station 3 may be included; and a necessary one(s) alone of the above-mentioned processing devices may be arranged in the processing station 3. In a case of a device unit to which an exposure device is connected, the cassette station 2 and the interface station 4 may be included, and further the wafer W may be transferred between the cassette C and the exposure device via the cassette station 2 and the interface station 4. In a case where the device unit executes a process other than exposure, the processing station 3 may be additionally provided.

Incidentally, patterning may be a process for repeatedly executing Post Exposure Bake (PEB) and development. The second and the following PEB and development is a process for adjusting a pattern that is formed on a resist film in the first PEB and development, and the above-mentioned chemical filters may be applied to device units that execute the second and the following PEB and development. Incidentally, the patterning process means a process from a process for forming a resist film of MOR to a process for developing the resist film, in a case where repeatedly executing PEB and development in such a manner, the above-mentioned development corresponds to the last development. Note that in repeatedly executing PEB and development, an etching process is assumed not to be executed on a film (namely, lower layer film) under the resist film until the adjustment is completed. In other words, patterning corresponds to a process from formation of a resist film to the last development before first etching of a lower layer film.

It has been mentioned that a configuration may be employed in which inert gas, which has passed through the chemical filter explained as the embodiments, is supplied to the cassette C and/or a waiting device arranged in a station. It is preferable to employ a configuration in which inert gas is supplied in such a manner in a system that causes a plurality of device units to execute patterning, because even in a case where access to one device unit by a transfer mechanism delays, it is possible to prevent change in quality of a resist film due to the wafer W waiting for a long time interval in the cassette C of the one device unit. The inert gas may be supplied to the cassette C and/or the waiting device not for causing the wafer W transferred to different device units to wait, but for more reliably reducing change in quality of a resist film until the wafer W is transferred to a transfer destination in transferring the wafer W in the same device unit.

Incidentally, materials constituting the filter parts 53 to 55 has been already exemplified; however, it is sufficient that the filter parts respectively remove different chemical substances, and thus not limited to the exemplifies ones. For example, activated carbon impregnated with a basic substance, such as potassium carbonate, may be employed for the acid filter part 53, and activated carbon activated carbon an acidic substance, such as phosphoric acid, may be employed for the base filter part 54. Moreover, structures of the filter parts 53 to 55 are not limited to the already-described ones, for example, an element may be employed, which is configured to form a layer by many granular activated carbons being sandwiched between non-woven fabrics. A substrate to be processed is not limited to a wafer; however, may be a substrate for manufacturing a flat panel display, or may be a mask substrate for manufacturing a mask for exposure, for example. Thus, a rectangular-shaped substrate may be processed.

### Supplement Related to MOR

A resist film of MOR will be explained as supplement. In the resist film, from Sn atoms in a portion that is exposed by an exposure device, ligands that are coordinated to the Sn atoms eliminate, and the many Sn atoms from which the ligands have eliminated bond to each other via oxygen (O) atoms. In other words, Sn atoms are oxidized to form a cross-linking structure, and a structure body of “—Sn—O—Sn—O—Sn—O—” is formed in an exposed region of a resist film. Note that a ratio between Sn atoms and O atoms in the cross-linking structure is not limited to “1:1” as described above. The exposed portion is insolubilized with respect to developer liquid by formation of the above-mentioned cross-linking structure, and PEB facilitates formation of the cross-linking structure. In development, a non-exposed region is removed, in which the cross-linking structure is not formed.

### Another Configuration Example of Wafer Processing System

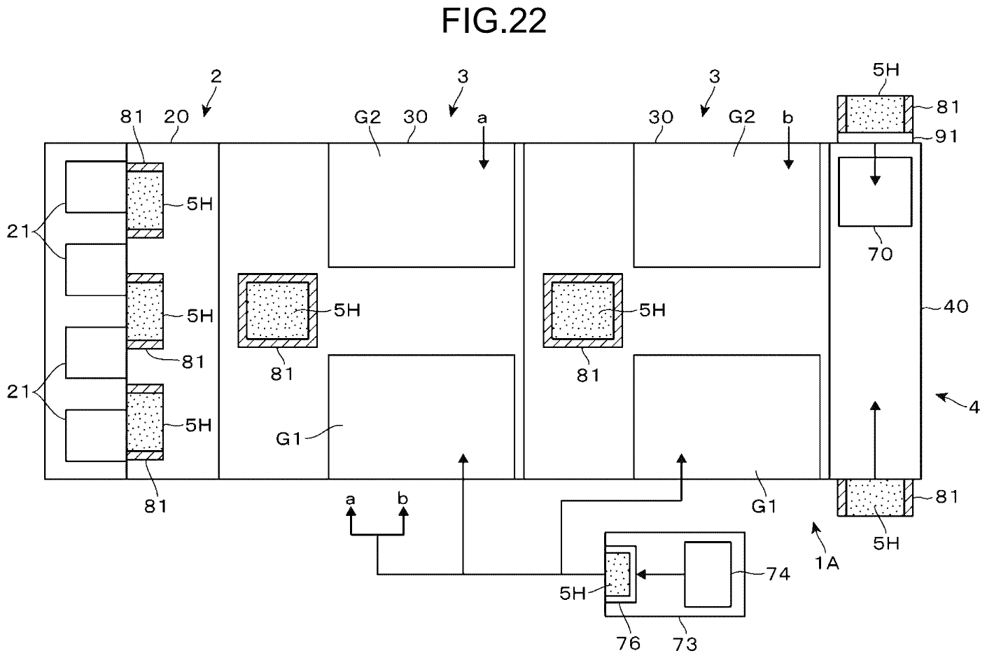

FIG. 22 is a plan view illustrating a wafer processing system 1A. The wafer processing system 1A is configured similarly to the wafer processing system 1, and hereinafter, a different point from the wafer processing system 1 will be mainly explained. In explanation of the wafer processing system 1A, a side where the cassette station 2 locates is a left side, a side where the interface station 4 locates is a right side, a side where the first block G1 locates is a front side, and a side where a second block locates is a rear side.

A chemical filter 5H is provided to each of the cassette station 2, the processing station 3, and the interface station 4 instead of the chemical filter 5. The gas supplying system 73 having been explained with reference to FIG. 12 is connected to the wafer processing system 1A. The chemical filter 5H is provided to the flow path 76 of the gas supplying system 73 instead of the chemical filter 5.

The chemical filter 5H provided to each station is provided to a flow path 82 of a rectangular-shaped tube body 81 whose inner part is formed as the flow path 82 of gas. Similar to the chemical filter 5, the chemical filter 5H includes the acid filter part 53, the base filter part 54, and the organic filter part 55; however, an alignment order of the above-mentioned filter parts is different from that of the chemical filter 5. Details of the chemical filter 5H will be mentioned later.

In the cassette station 2, the tube bodies 81 are arranged in positions that are on a left side wall constituting the housing 20 and that are above the cassette placement plates 21, and an upper-stream side of the flow path 82 formed by each of the tube bodies 81 is towards the left side so as to face an external space of the housing 20. In each of the processing stations 3, the tube body 81 is arranged on an upper wall constituting the housing 30, and an upper-stream side of the flow path 82 formed by the tube body 81 is towards the above so as to face an external space of the housing 30. In the interface station 4, the tube bodies 81 are arranged so as to respectively protrude forward and backward from a front side wall and a rear side wall of the housing 40. An upper-stream side of the flow path 82 formed by the front tube body 81 is towards the front so as to face an external space of the housing 40, and an upper-stream side of the flow path 82 formed by the rear tube body 81 is toward the rear so as to face an external space of the housing 40.

As described above, the tube bodies 81, each of which includes the corresponding chemical filter 5H, are arranged in the stations 2, 3, and 4. For each of the stations 2, 3, and 4, external air of the wafer processing system 1A is taken therein via the chemical filter 5H arranged in the corresponding station, and the air is supplied into the housings 20, 30, and 40 constituting the stations. The above-mentioned taking and supplying of air are performed by the fans 51 that are arranged on down-stream sides of the chemical filters 5H on flow paths of air which are formed in the stations. Note that instead of taking in external air of the wafer processing system 1A, for example, air whose temperature or humidity is adjusted by an external device may be supplied to a supply pipe that is connected to a housing 81, so as to take in air.

A filter 90 for removing extraneous substances from air is arranged on a down-stream side of the fan 51 on a flow path of the air, and the air is supplied into a housing via the filter 90. The filter 90 is an Ultra Low Penetration Air (ULPA) filter, for example. As described above, a flow path on which the chemical filter 5H, the fan 51, and the filter 90 are arranged towards a down-stream side is formed in each station, and the above-mentioned tube body 81 forms a part of the flow path. Hereinafter, for convenience of explanation, the filter 90 may be referred to as an extraneous substance removing filter 90.

The processing station 3 will be further explained. Into the wafer transferring area 32 of the processing station 3, air is supplied from the above via a flow path including the chemical filter 5H, the fans 51, and the extraneous substance removing filter 90 that are arranged in the housing 30. Into the processing devices 70 respectively included in the first block G1 and the second block G2, as described with reference to FIG. 12, gas whose temperature and humidity are adjusted is supplied from the gas supplying system 73 via the chemical filter 5H of the gas supplying system 73.

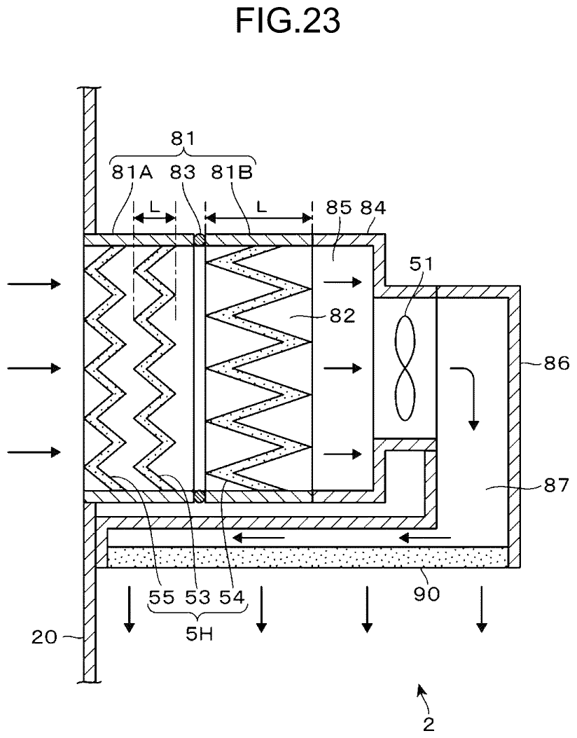

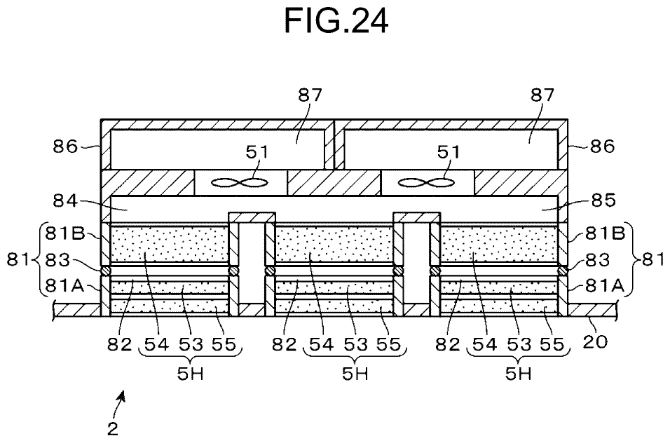

Subsequently, regarding the cassette station 2, details of a vertical front cross sectional view illustrated in FIG. 23 and a lateral cross sectional plan view illustrated in FIG. 24 will be explained.

Furthermore, configurations of the chemical filter 5H and the tube body 81 will be more specifically explained. A metallic tube body 81A and a metallic tube body 81B are connected with each other in an axial direction of the tube bodies via a connection member 83 so as to form the tube body 81. The tube body 81A forms an upper-stream side of the flow path 82, and the tube body 81B forms a down-stream side of the flow path 82. The connection member 83 is an elastic member that is formed in ring-shaped along peripheries of the tube bodies 81A and 81B, and is specifically a gasket, for example.

The organic filter part 55, the acid filter part 53, and the base filter part 54 are arranged in this order towards a down-stream side of the flow path 82 so as to configure the chemical filter 5H, and the organic filter part 55 and the acid filter part 53 are arranged in the tube body 81A and the base filter part 54 is arranged in the tube body 81B. In the present embodiment, the organic filter part 55 is a sheet including activated carbon, the acid filter part 53 is a sheet including impregnated activated carbon, and the base filter part 54 is a sheet including cation exchange resin. For example, each of the sheets is formed by weaving a fiber, and is arranged so as to partition the flow path 82 into an upper-stream side and a down-stream side. Each of the filter parts formed as a sheet in such a manner is bent into pleat-shaped as described with reference to FIG. 17.

Regarding mountains formed by folding a sheet in such a manner, assume that a distance between adjacent apexes in a direction of the flow path 82 is an apparent thickness L, in the present embodiment, in order to achieve life elongation of the base filter part 54, the apparent thickness L of the base filter part 54 is larger than the apparent thicknesses L of the organic filter part 55 and the acid filter part 53. Note that in a case where the apparent thickness L is set to be relatively large as described above, a volume of a space between folds formed by a sheet of the base filter part 54 is also relatively large. Therefore, a pressure loss reduces when gas passes through a region on the flow path 82, in which the base filter part 54 is arranged. Thus, in a case where the base filter part 54, which is assumed to be formed in flat-shaped, has a relatively high pressure loss; in terms of reduction in a pressure loss of the flow path 82, in addition to life elongation of the base filter part 54, it is efficient that relation between the apparent thicknesses L of the filter parts is set to the above-mentioned one. Note that a case where the base filter part 54 has a relatively high pressure loss includes a case where a pressure loss thereof is higher than the organic filter part 55 or the acid filter part 53, which is similarly assumed to be formed in flat-shaped.

Note that in the present embodiment, the apparent thickness L of the base filter part 54 is set to be large, and thus the tube body 81 is relatively long. In a case where the tube body 81 is integrally formed, there presents possibility that difficulty for manufacturing and/or processing increases due to a size thereof, thus the tube body 81 is constituted of the tube bodies 81A and 81B that are separated members, and the tube bodies 81A and 81B are configured to be connect with each other via the connection member 83. In arranging the filter parts 53 to 55 in the tube body 81, provision of the connection member 83 causes increase in a space formed between the acid filter part 53 and the base filter part 54 by an amount of a thickness of the connection member 83. As the example described with reference to FIG. 18, the above-mentioned space is utilized, and air having passed through the acid filter part 53 diffuses to be supplied into the base filter part 54, so that it is preferable because reduction in life in a local position of the base filter part 54 is suppressed.

In the cassette station 2, the plurality of tube bodies 81, for example, the three tube bodies 81 are aligned in a front-rear direction at the same height. Each of the tube bodies 81 is arranged such that an axis thereof extends in a left-right direction in the housing 20 constituting the cassette station 2, and an upper-stream side of the flow path 82 is connected to an opening on a left side wall of the housing 20 as described above.

A suction dedicated housing 84 is arranged on a right side of each of the tube bodies 81. The suction dedicated housing 84 is long in a front-rear direction so as to form a space 85 that is partitioned from the surroundings, and a down-stream side of the flow path 82 of each of the tube bodies 81 is connected to the space 85. The two fans 51 are provided to the suction dedicated housing 84 such that rotational axes thereof extend in a left-right direction, and the fans 51 are located on a right side of the space 85 apart from each other in a front-rear direction. Each of the fans 51 is capable of applying suction to the flow paths 82 of the tube bodies 81 via the space 85. Thus, the single fan 51 applies suction to flow paths of the plurality of tube bodies 81.

Upper-stream ends of two ducts 86 are aligned back and forth on a right side of the suction dedicated housing 84 to be individually connected to the suction dedicated housing 84. Air suctioned by the rear fan 51 of the two fans 51 is supplied to a flow path 87 in the rear duct 86, and air suctioned by the front fan 51 is supplied to the flow path 87 in the front duct 86. A down-stream side of each of the ducts 86 extends downward, and then bends towards the left. A lower side of a portion extending towards the left in each of the duct 86 is opened. The extraneous substance removing filter 90 is arranged so as to cover the opened portion of the duct 86 from underneath, and a lower-stream edge portion of the flow path 87 is located above the extraneous substance removing filter 90 as a flat space. Thus, as illustrated in FIG. 23, the flow path 87 is formed in toppled L-shaped in a front view, and the chemical filter 5H locates above the extraneous substance removing filter 90.

Air, which is supplied by the fans 51 to the flow path 87 in the duct 86 via the chemical filter 5H from the outside of the wafer processing system 1A, is supplied downwards via the extraneous substance removing filter 90. A region under the extraneous substance removing filter 90 to which the air is supplied is a region to which the wafer W is transferred by the wafer transferring devices 22 and 23.

In this way, a flow path from the chemical filter 5H to the extraneous substance removing filter 90 is formed by the tube body 81, the suction dedicated housing 84, and the duct 86, and the flow path is bent to be formed in toppled U-shaped. The chemical filter 5H includes the filter parts 53 to 55 so that a size thereof is larger than a chemical filter having a configuration including one of two alone of the filter parts 53 to 55; however, in a case where the flow path is bent as described above, increase in a size of the flow path in a left-right direction is suppressed even when the chemical filter 5H is arranged. In other words, in accordance with a flow path configuration according to the present embodiment, it is possible to arrange the relatively large chemical filter 5H in a flow path direction without increasing a size of the flow path in a left-right direction.

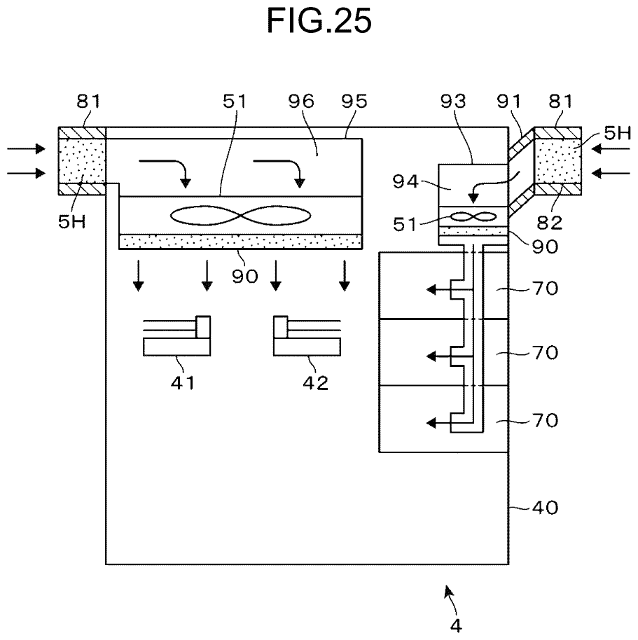

Next, the interface station 4 will be explained with reference to a side view illustrated in FIG. 25. FIG. 25 illustrates the interface station 4 when viewed from a right side. The plurality of processing devices 70 is laminated to be arranged on a rear side of the housing 40 of the interface station 4 according to the present embodiment. Processes to be executed by the processing devices 70 are not limited, the processes include a process for cleaning the wafer W before exposure by an exposure device, for example. In the interface station 4, flow paths are formed such that air absorbed from the different chemical filters 5H is respectively supplied to different regions. Supply targets of air having passed through the chemical filter 5H of the tube body 81 on a rear side are the processing devices 70. A supply target of air having passed through the chemical filter 5H of the tube body 81 on a front side is a region outside of the processing devices 70, in which the wafer transferring devices 41 and 42 move.

A front edge of the tube body 81 arranged on a rear side of the housing 40 is connected with a duct 91 that diagonally extends towards the above from a side wall of the housing 40 in a side view. The flow path 82 in the tube body 81 communicates, via the duct 91, with a flow path 94 that is formed by a flow path forming member 93 arranged in the housing 40. The fan 51 and the extraneous substance removing filter 90 are arranged on the flow path 94 towards a down-stream side. A lower-stream edge portion of the flow path forming member 93 is configured as a duct, for example, to be connected with the processing devices 70. According to the above-mentioned configuration, air, which is taken into the housing 40 via the chemical filter 5H on a rear side by the fan 51 on the flow path 94, is supplied to the processing devices 70 via the extraneous substance removing filter 90.

A rear edge of the tube body 81 arranged on a front side of the housing 40 is connected with a side wall of the housing 40. The flow path 82 in the tube body 81 communicates with a flow path 96 that is formed by a flow path forming member 95 arranged in the housing 40. The fan 51 and the extraneous substance removing filter 90 are arranged on the flow path 96 towards a down-stream side. According to the above-mentioned configuration, air, which is taken into the housing 40 via the chemical filter 5H on a front side by the fan 51 of the flow path 96, is supplied to moving regions of the wafer transferring devices 41 and 42 via the extraneous substance removing filter 90.

Similar to the processing station 3, in the interface station 4, the chemical filter 5H may be arranged in an upper portion of the housing 40 of a station. However, in a case where the chemical filter 5H is arranged on a side of the housing 40 as described above, it is possible to prevent the tube body 81 from protruding out of an upper wall of the housing 40, as a result, it is possible to reduce a height of the interface station 4. For example, in a case where a configuration member of an exposure device locates above the interface station 4, in order to prevent interference with the configuration member, it is effective that a height of the interface station 4 is reduced in such a manner.

In arranging the tube body 81 including the chemical filter 5H on a side wall of the housing 40, in a case where the tube body 81 interferes with a member arranged on the side wall of the housing 40, a configuration may be employed in which the duct 91 intervenes between the tube body 81 and the housing 40 as exemplified as the tube body 81 on a rear side. In accordance therewith, the interference may be avoided. Thus, if there is not such an interference object, the duct 91 may be omitted, and if necessary, the duct 91 may be arranged between the tube body 81 on a front side and a wall of the housing 40. Assume a case where a flow path extending into the housing 40 from the housing 81 arranged on a side wall of the housing 40 via the duct 91 as illustrated in FIG. 25 is replaced with a flow path through which gas flows downward from a side to an inside of the housing 40. In this case, in addition to the above-mentioned avoidance of interference, a flow path extending upwards is not included, and thus air is easily supplied to the processing devices 70 beneath the housing 81. From view point of the above-mentioned avoidance of interference alone, a direction of the duct 91 may be along a horizontal direction; however, the disclosed example is preferable for efficiently supplying air. In the interface station 4, a supply target of air having passed through the chemical filter 5H on a rear side is the processing device 70, and a supply target of air having passed through the chemical filter 5H on a front side is a transfer region of the wafer W; however, a supply target of air may be appropriately set in accordance with an arrangement position of the processing device 70 in the housing 40 and the like. Thus, air may be supplied to the processing device 70 via the chemical filter 5H on a front side.

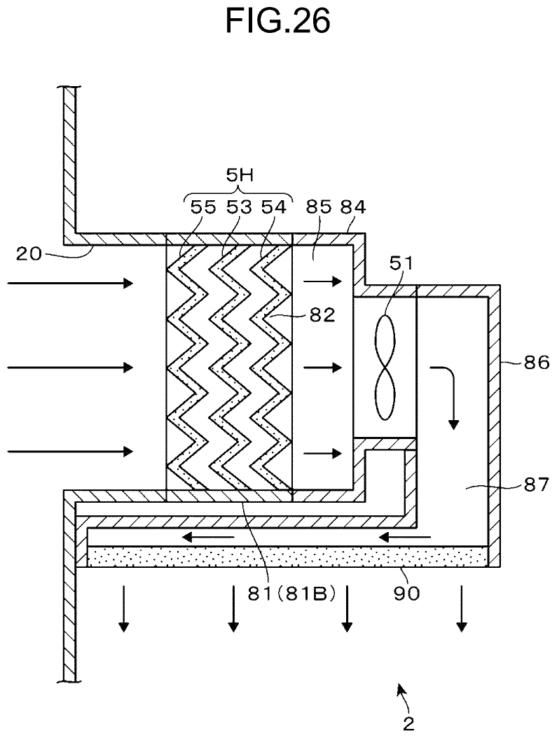

In FIG. 23, the organic filter part 55 and the acid filter part 53 are separately illustrated from each other; however, may be in contact with each other. In the present embodiment, the apparent thickness L of the base filter part 54 of the filter parts 53 to 55 is larger than the apparent thicknesses L of the other filter parts; however, not limited thereto, a filter part having the large apparent thickness L may be decided in accordance with an environment where the wafer processing system 1A is arranged. The apparent thicknesses L of a specific filter part is not limitedly larger than the apparent thickness L of another filter part. In a case where thicknesses L of the filter parts are relatively small, the tube body 81 is not limitedly constituted of the tube bodies 81A and 81B, and may be constituted of the tube body 81B alone as illustrated in FIG. 26. Note that an alignment order of the filter parts 53 to 55 is not limited to the examples illustrated in FIG. 23 and FIG. 26, and the alignment orders described as other examples may be employed.

In the configuration example of the wafer processing system 1 described prior to the wafer processing system 1A, a chemical filter locates on a down-stream side of the fan 51; however, a configuration may be employed in which a chemical filter locates on an upper-stream side of the fan 51 as in the wafer processing system 1A. In the wafer processing system 1, the extraneous substance removing filter 90 is not illustrated; however, may be provided similarly to the wafer processing system 1A.

The examples have been described in which the chemical filter 5 or 5H is provided to a wafer processing system configured to form a resist film of MOR and the gas supplying system 73 attached to the wafer processing system; however, the chemical filters 5 and 5H are not limitedly provided to such a system. Specifically, the chemical filter 5 or 5H may be provided to a wafer processing system configured to form a resist film by using a chemically amplified type photoresist and the gas supplying system 73 attached to the wafer processing system. The wafer processing system configured to form a chemically amplified type resist film may be configured similarly to the above-mentioned wafer processing system, for example, except for difference in a type of photoresist to be supplied to the wafer W.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

### Evaluation Test

In executing a patterning process on the wafer W, gas including organic compounds was supplied to a partial region (may be referred to as first region) of a surface of the wafer W in some step, and sizes of CD were compared between a pattern formed in the first region and a pattern formed in a second region to which the gas was not supplied. The gas was supplied in one of the first stage to the fourth stage. The first stage was a stage before formation of a resist film made of MOR, and the second stage was a stage before exposure by an exposure device after formation of the resist film. The third stage was a stage before execution of PEB after exposure, and the fourth stage was a stage before execution of development after execution of PEB. Note that in the evaluation test, development and PEB were not repeated.

In the evaluation test, an exposure device whose light source was krypton fluoride (KrF) was used. Gas of organic compound to be supplied was changed for each of the wafers W. Specifically, gas was supplied, which was obtained from each of mixed solution of PGMEA and acetic acid, PGMEA, acetic acid, mixed solution of propylene glycol monomethyl ether and PEGMEA, hexamethyl disilazane, cyclohexanone, ethyl methyl ketone, and acetone. The mixed solutions of PEGMEA and acetic acid were used, whose weight percentage of contained acetic acid were 28, 58, and 40%.

As a result of the evaluation test, in the wafers W to which gas obtained from mixed solution of PEGMEA and acetic acid or gas of acetic acid was supplied in the second stage, the third stage, or the fourth stage; a size of CD was different between the first region and the second region. More specifically, in the wafers W to which gas including acetic acid was supplied in the second stage or the third stage, CD in the first region was smaller than CD in the second region. In the wafer W to which gas including acetic acid was supplied in the fourth stage, CD in the first region was larger than CD in the second region. In the other wafers W, obvious difference was not found in a size of CD between the first region and the second region. From the result of the evaluation test, acetic acid was estimated to contribute to fluctuation in CD of a pattern. Thus as described in the embodiments, it can be said to be efficient that a chemical filter is configured to include the organic filter part 55, and arranging the acid filter part 53 and the base filter part 54 in the order described in the embodiments so as to prevent discharge of acetic acid generated from decomposed PGMEA.

What is claimed is:

1. A substrate processing apparatus to be used in patterning that is executed by exposing and developing a metal containing resist film formed on a substrate, wherein
a chemical filter is arranged in the substrate processing apparatus, the chemical filter including a plurality of filter parts aligned towards a down-stream side on a flow path that supplies gas into the substrate processing apparatus to remove respective different substances in the gas, and
the plurality of filter parts includes:
an acid filter part that removes an acidic substance; and
a base filter part that removes a basic substance.

2. The substrate processing apparatus according to claim 1, wherein
the acid filter part is arranged on a down-stream side of the base filter part.

3. The substrate processing apparatus according to claim 2, wherein
the plurality of filter parts includes an organic filter part that removes an organic substance in the gas, and
the organic filter part is arranged on the flow path on an upper-stream side of the base filter part.

4. The substrate processing apparatus according to claim 1, wherein
the plurality of filter parts includes an organic filter part that removes an organic substance in the gas, and
the acid filter part, the organic filter part, and the base filter part are arranged in this order towards a down-stream side.

5. The substrate processing apparatus according to claim 1, wherein
a first chemical filter and a second chemical filter are arranged as the chemical filter for each of a first flow path and a second flow path that supply the gas to respective different spaces in the substrate processing apparatus, and
the first chemical filter and the second chemical filter are different in at least one of presence/absence of an organic filter part that removes an organic substance in the gas, an alignment order of the filter parts, and a thickness of a filter part having a same removal target.

6. The substrate processing apparatus according to claim 5, wherein
the first chemical filter of the first chemical filter and the second chemical filter includes the organic filter part, and
in the acid filter part or the base filter part, a thickness of the second chemical filter is larger than a thickness of the first chemical filter.

7. The substrate processing apparatus according to claim 1, wherein
a gap is provided between one of the plurality of filter parts and another filter part that is arranged next to the one filter part in a case where the flow path is viewed towards a down-stream side.

8. A substrate processing method to be used in patterning that is executed by exposing and developing a metal containing resist film formed on a substrate, the method comprising:
supplying gas having passed through a chemical filter to a substrate processing apparatus for executing the patterning, the chemical filter including a plurality of filter parts that aligns towards a down-stream side on a flow path to remove respective different substances in the gas, wherein
the plurality of filter parts includes:
an acid filter part that removes an acidic substance; and
a base filter part that removes a basic substance.

9. A chemical filter used in a substrate processing apparatus configured to execute patterning that is executed by exposing and developing a metal containing resist film formed on a substrate, the chemical filter comprising:
a plurality of filter parts aligned towards a down-stream side on a flow path that supplies gas into the substrate processing apparatus to remove respective different substances in the gas, wherein
the plurality of filter parts includes:
an acid filter part that removes an acidic substance; and
a base filter part that removes a basic substance.
